(19) United States
(12) Patent Application Publication
(10) Pub. No.: US 2025/0046683 A1
(43) Pub. Date: Feb. 6, 2025

(54) WIREBOND ELECTROPLATING STRUCTURE FOR FULL CUT WETTABLE FLANK STRUCTURES FOR SON PACKAGES

(71) Applicant: Texas Instruments Incorporated, Dallas, TX (US)

(72) Inventor: Steven Kummerl, Carrollton, TX (US)

(21) Appl. No.: 18/362,276

(22) Filed: Jul. 31, 2023

(51) Int. Cl. H01L 23/495; H01L 21/56; H01L 23/00; H01L 23/31

(52) U.S. Cl. CPC H01L 23/49541; H01L 21/565; H01L 23/3107; H01L 24/48; H01L 2224/48247; H01L 2924/181

(57) ABSTRACT

An electronic device with a small outline no-lead package having a molded package structure and conductive leads with plated sidewalls exposed along opposite lateral sides of the package structure, a semiconductor die at least partially enclosed by the molded package structure, a first bond wire enclosed by the molded package structure and connected between a first one of the conductive leads and the semiconductor die, and a second bond wire having a first end and an unterminated second end exposed along a further side of the package structure.

### BACKGROUND

Solder wetting is important in the manufacture of electronic systems to provide good solder connection between electronic devices and a host system such as a printed circuit board (PCB). Conductive leads of electronic devices can be coated to mitigate corrosion prior to installation on a circuit board and to facilitate solder connection when the device is soldered to a circuit board. Coating by electroplating is an effective technique for applying tin or other materials to the bottoms and sidewalls of small outline no lead (SON) electronic devices during fabrication. However, insufficient electrical conductivity to the lead structures during electroplating can inhibit effective coating of the lead surfaces. Providing tie bars and other conductive structures permanently connected to interior portions of prospective device leads in a lead frame panel array can help grounding or other electrical referencing of the prospective leads during electroplating. However, such electrical grounding structures increase the area of an electronic device and inhibit efforts towards reducing device size and/or increasing component and/or power density of the electronic device and the host system. For example, adding additional tie bar structures can greatly limit the size of a die paddle or die attach pad for mounting a semiconductor die in the device. Other solutions can involve tedious lead frame redesign, and in many cases cause the die to be a chip on lead (COL) style of package that must use a non-conductive die attach film (DAF), which inhibits the ability to use existing lead frames and increases manufacturing cost and complexity.

### SUMMARY

In one aspect, an electronic device includes a semiconductor die, conductive leads in first and second rows along respective opposite sides of a package structure, a first bond wire having a first end connected to a first one of the conductive leads and a second end connected to the semiconductor die, and a second bond wire having a first end connected to a second one of the conductive leads and an unterminated second end exposed along a further side of the package structure.

In another aspect, an electronic device includes a small outline no-lead package having a molded package structure and conductive leads with plated sidewalls exposed along opposite lateral sides of the package structure, as well as a semiconductor die at least partially enclosed by the molded package structure, a first bond wire enclosed by the molded package structure and connected between a first one of the conductive leads and the semiconductor die, and a second bond wire having a first end and an unterminated second end exposed along a further side of the package structure.

In a further aspect, a method of fabricating an electronic device includes, for a first unit area of a lead frame panel array having unit areas arranged in rows along a first direction and columns along an orthogonal second direction, forming a first bond wire to connect a first conductive lead of the first unit aera to a semiconductor die of the first unit area, and for the first unit area, forming a second bond wire to connect a second conductive lead of the first unit aera to a conductive feature of a second unit area of the lead frame panel array. The method includes cutting a conductive feature of the lead frame panel array along a first direction between the first unit area and a neighboring third unit area of the lead frame panel array to separate the conductive leads of the first unit area from a conductive structure of the neighboring third unit area of the lead frame panel array, as well as performing an electroplating process that forms a plated surface on sidewalls of the conductive leads of the first unit aera and separating a packaged electronic device from the lead frame panel array.

### BRIEF DESCRIPTION OF THE DRAWINGS

FIG. 1 is a top plan view of an electronic device with unterminated bond wires.

FIG. 1A is a sectional side elevation view of the electronic device taken along line 1A-1A of FIG. 1.

FIG. 1B is a sectional side elevation view of the electronic device taken along line 1B-1B of FIG. 1.

FIG. 1C is a side elevation view of the electronic device of FIG. 1 showing cut ends of unterminated bond wires exposed along a sidewall of the molded package structure of the device.

FIG. 2 is a flow diagram of a method of fabricating an electronic device.

FIGS. 3-9 are top plan views of the electronic device of FIG. 1 undergoing fabrication processing in a panel array with rows and columns of unit areas according to an implementation of the method of FIG. 2.

### DETAILED DESCRIPTION

In the drawings, like reference numerals refer to like elements throughout, and the various features are not necessarily drawn to scale. Also, the term “couple” or “couples” includes indirect or direct electrical or mechanical connection or combinations thereof. For example, if a first device couples to or is coupled with a second device, that connection may be through a direct electrical connection, or through an indirect electrical connection via one or more intervening devices and connections. One or more operational characteristics of various circuits, systems and/or components are hereinafter described in the context of functions which in some cases result from configuration and/or interconnection of various structures when circuitry is powered and operating. Unless otherwise stated, “about,” “approximately,” or “substantially” preceding a value means +/−10 percent of the stated value. One or more operational characteristics of various circuits, systems and/or components are hereinafter described in the context of functions which in some cases result from configuration and/or interconnection of various structures when circuitry is powered and operating. One or more structures, features, aspects, components, etc. may be referred to herein as first, second, third, etc., such as first and second terminals, first, second, and third, wells, etc., for ease of description in connection with a particular drawing, where such are not to be construed as limiting with respect to the claims.

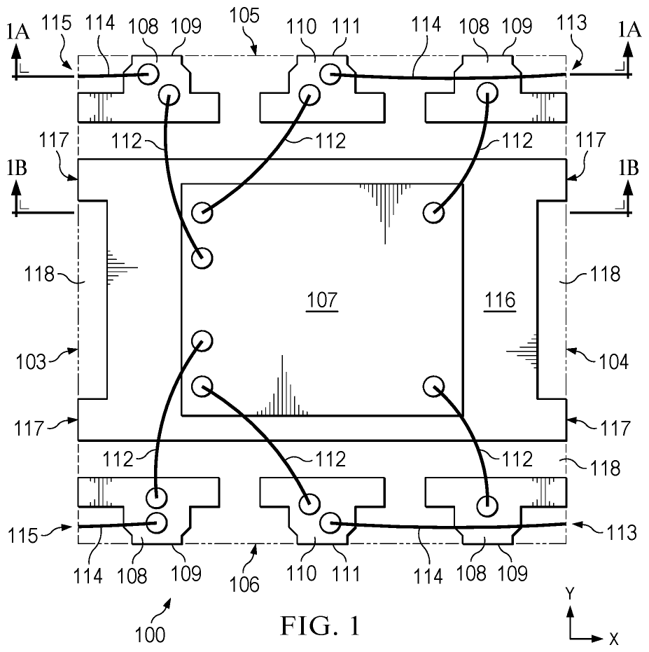

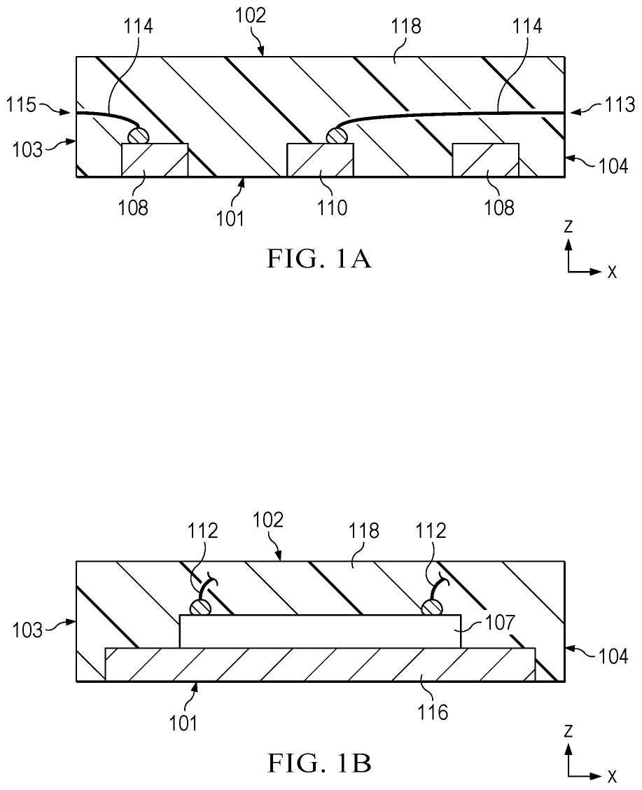

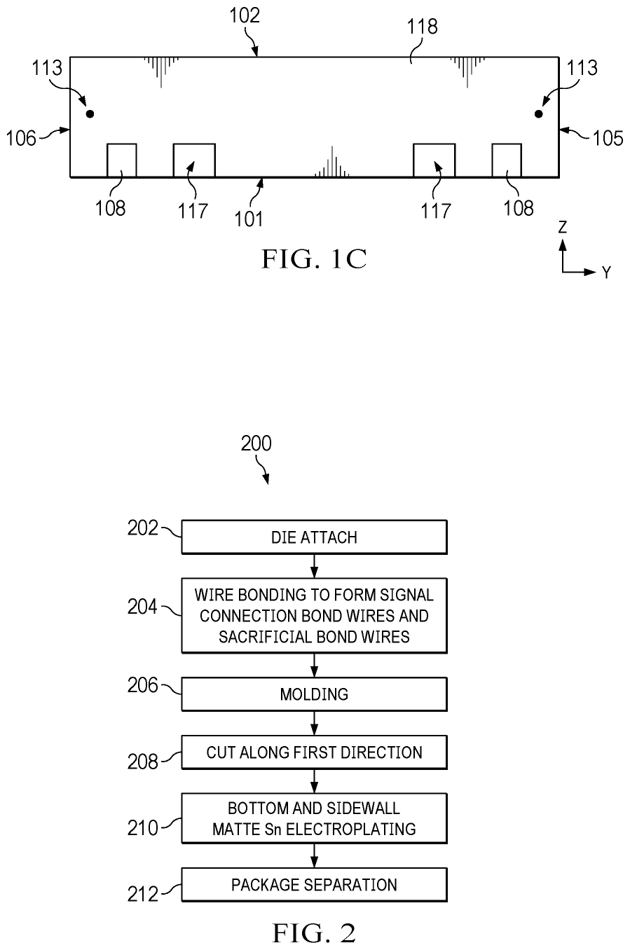

FIGS. 1-1C illustrate an example electronic device 100 in an example position in a three-dimensional space with a first direction X (FIGS. 1-1B), a perpendicular (orthogonal) second direction Y (FIGS. 1 and 1C), and a third direction Z (FIGS. 1A-1C) that is perpendicular (orthogonal) to the respective first and second directions X and Y. Structures or features along any two of these directions are orthogonal to one another. FIG. 1 shows a top view of the electronic device 100, FIG. 1A shows a sectional side view taken along line 1A-1A of FIG. 1, and FIG. 1B shows a sectional side view taken along line 1B-1B of FIG. 1. FIG. 1C shows a side view of the electronic device 100 illustrating cut ends of unterminated bond wires exposed along a sidewall of the molded package structure of the device.

As best shown in FIGS. 1A-1C, the electronic device 100 has opposite first and second (e.g., bottom and top) sides 101 and 102, respectively, which are spaced apart from one another along the third direction Z. The electronic device 100 has opposite third and fourth sides 103 and 104 (FIGS. 1-1B) that are spaced apart from one another along the first direction X and extend along the second direction Y. The electronic device 100 also includes respective fifth and sixth sides 105 and 106 (FIGS. 1 and 1C) spaced apart from one another along the second direction Y.

The electronic device 100 has a molded package structure 118 that forms parts of the device sides 101-106. In the illustrated example, the respective sides 101-106 are generally planar, the bottom and top sides 101 and 102 extend in respective X-Y planes, and the sides 103 and 104 extend in respective Y-Z planes of the second and third directions Y and Z. The sides 101-106 in one example have substantially planar outer surfaces. In other examples (not shown), one or more of the sides 101-106 have curves, angled features, or other non-planar surface features.

The electronic device 100 is a small outline no lead (SON, also referred to as a dual row quad flat no lead (QFN) device with rows of conductive leads along the opposite lateral sides 105 and 106. The electronic device 100 includes a semiconductor die 107 (FIGS. 1 and 1B) attached to a die attach pad 116, for example, using an adhesive (not shown). The semiconductor die 107 includes one or more electronic circuit components and top side conductive features (e.g., bond pads, not shown) for electrical connection of the circuit component or components in a circuit.

As shown in FIG. 1, each row of conductive leads includes conductive end leads 108 at opposite ends of the respective row, along with one or more intermediate leads 110 between the conductive end leads 108. In the illustrated example, the first row of the conductive leads 108, 110 extends along the fifth side 105, and the second row of the conductive leads 108, 110 extends along the sixth side 106 of the package structure 118.

Each of the conductive end leads 108 of the first and second rows has a plated surface 109 exposed along the respective sides 105 and 106 of the package structure 118, and each of the conductive intermediate leads 110 of the first and second rows has a plated surface 111 exposed along the respective side 105 and 106. The leads 108 and 110 are also exposed along the bottom side 101 of the electronic device, and the exposed bottoms of the leads 108 and 110 have plated surfaces in one example. In the illustrated example, the bottom side of the die attach pad also has a plated surface. In one example, the conductive leads 108 and 110 are or include copper, and the die attach pad 116 is or includes copper. In this or another example, the plated surfaces 109 and 111 are or include tin (Sn) with a matte finish.

As further shown in FIG. 1, one or more of the leads 108, 110 are connected to a corresponding respective conductive feature (e.g., bond pad) of the semiconductor die 107 by a respective first bond wire 112. The first bond wires 112 provide electrical connections between the respective leads 108, 110 and the circuitry or components of the semiconductor die 107. The individual first bond wires 112 have a first end connected to a first one of the conductive leads 108, 110 and a second end connected to the semiconductor die 107.

As shown in FIGS. 1 and 1A, the electronic device 100 also includes one or more unterminated second bond wires 114. The second bond wires 114 are referred to herein as unterminated as having second ends that are not connected to another circuit feature or component, even though the first end of the respective second bond wires 114 are connected to a lead, a die attach pad, or a tie bar. The individual second bond wires 114 have a first end connected to a respective one of the conductive leads 108, 110 or to another conductive feature of the electronic device (e.g., a tie bar, the die attach pad, etc.) as well as an unterminated second end 113, 115 exposed along a respective one of the third and fourth sides 103 and 104 of the package structure 118.

The unterminated second bond wires 114 provide a temporary ground or other electrical connection to facilitated electroplating of the plated surfaces 109 and 111 of the leads 108 and 110 during manufacturing as described further below in connection with FIG. 2. The unterminated second bond wires 114 facilitate connection of the intermediate leads 110 to an electroplating system during electroplating following initial cutting operation that separates the intermediate leads 110 from other portions of a starting lead frame panel array. The second bond wires 114 are initially connected between the intermediate leads 110 and a conductive feature (e.g., a lead 108, a tie bar, a die attach pad 116, etc.) of another unit area of the lead frame panel array or strip, and subsequent cutting or other separation process after electroplating cuts the second bond wires 114, leaving the remnant unterminated second bond wires 114. Such temporary second bond wires 114 can also be used to enhance the electroplating of one or more end leads 108.

The temporary second bond wire approach provides a solution to enhance electroplating and enable a full cut wettable flank structure without increasing device size or cost, and without requiring redesign of existing lead frames for small outline electronic devices. By wire bonding to a neighboring package unit area on the lead frame strip, a temporary electrical connection structure is created that will be sawn through completely when the package is fully singulated. This enables existing lead frames to be used without the need for additional tie bar structures that could limit die attach pad size to accommodate the die. The use of the second bond wires 114 is a simple manufacturing modification to the otherwise existing wire bonding processing and does not require lead frame redesign. Moreover, the unterminated second bond wires 114 are electrically isolated once the package is fully singulated.

The resulting electronic device 100 provides a small outline no-lead package with the conductive leads 108 and 110 having plated sidewalls exposed along opposite lateral sides 105 and 106 of the package structure 118. The semiconductor die 107 in this example is at least partially enclosed by the molded package structure 118. The first bond wires 112 in this example are enclosed by the molded package structure 118 and are connected between a respective one of the conductive leads 108, 110 and a corresponding bond pad of the semiconductor die 107. The individual second bond wires 114 include a first end and an unterminated second end (e.g., 113 and 115 in FIGS. 1, 1A, and 1C) that is exposed along a corresponding one of the third and fourth sides 103 and 104 of the package structure 118.

As shown in FIG. 1, one of the second bond wires 114 has a first end connected to a first conductive intermediate lead 110 in the first row along the fifth side 105, and another one of the second bond wires 114 has a corresponding first end connected to a second conductive intermediate lead 110 of the second row along the sixth side 106. These second bond wires 114 have respective second ends 113 that are exposed outside the package structure 118 along the fourth side 104 and help provide electrical connection to the corresponding conductive intermediate leads 110 by temporary connection to conductive features of a neighboring unit area during electroplating to facilitate adequate plating of the plated surfaces 111.

The electronic device 100 in the illustrated example also has another one of the second bond wires 114 with a first end that is connected to one of the conductive end leads 108 of the first row along the fifth side 105 (e.g., the upper left end lead 108 in FIG. 1), and another one of the second bond wires 114 has a first end that is connected to one of the conductive end leads 108 of the second row along the sixth side 106 (e.g., the lower left end lead 108 in FIG. 1). These further second bond wires 114 have corresponding second ends 115 that are exposed outside the package structure 118 along the third side 103 and provide a ground or other electrical connection from the illustrated end conductive leads 108 to intermediate leads of a neighboring unit area during electroplating in a panel or strip arrangement with rows and columns of lead frame unit areas as described further below.

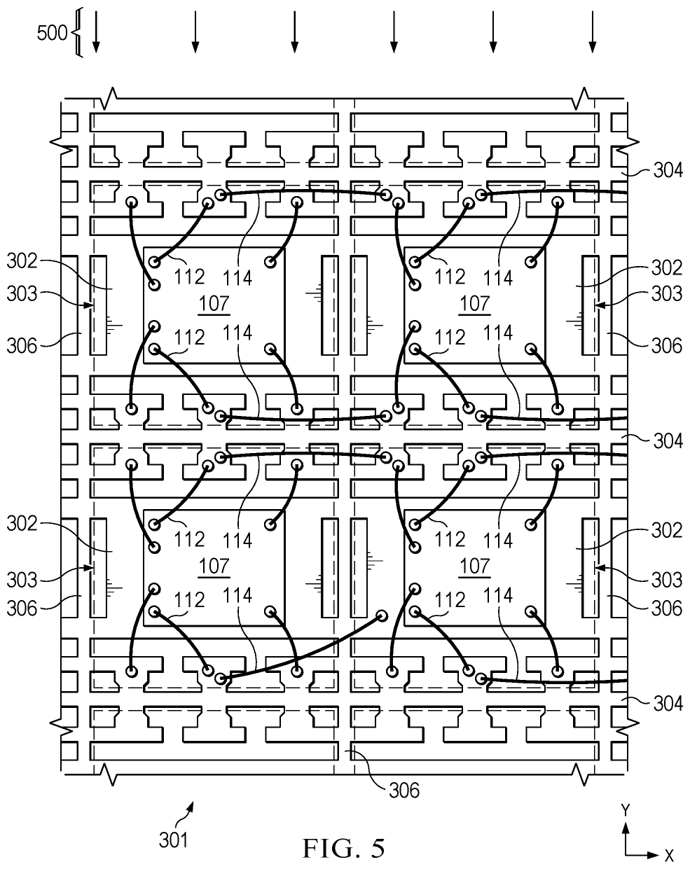

In a given implementation, moreover, further instances of an unterminated bond wire 114 can have a first end connected to a die attach pad 116, a tie bar 117 (e.g., extending from the die attach pad 116 and exposed outside the package structure 118 along one of the sides 103, 104) or other conductive structure, as well as an unterminated second end exposed along the third and fourth sides 103, 104 of the package structure 118, for example, as illustrated in FIGS. 5-9 below. In these or other examples, one of the first bond wires 112 can overlie one of the second bond wires 114 or vice versa, an example of which is illustrated in FIG. 5 below. The positional extent, height, and termination locations of the first bond wires 112 and the second bond wires 114 can be tailored for a given implementation in order to avoid short-circuiting of any two bond wires 112, 114, including providing one bond wire that overlies another bond wire without contact there between.

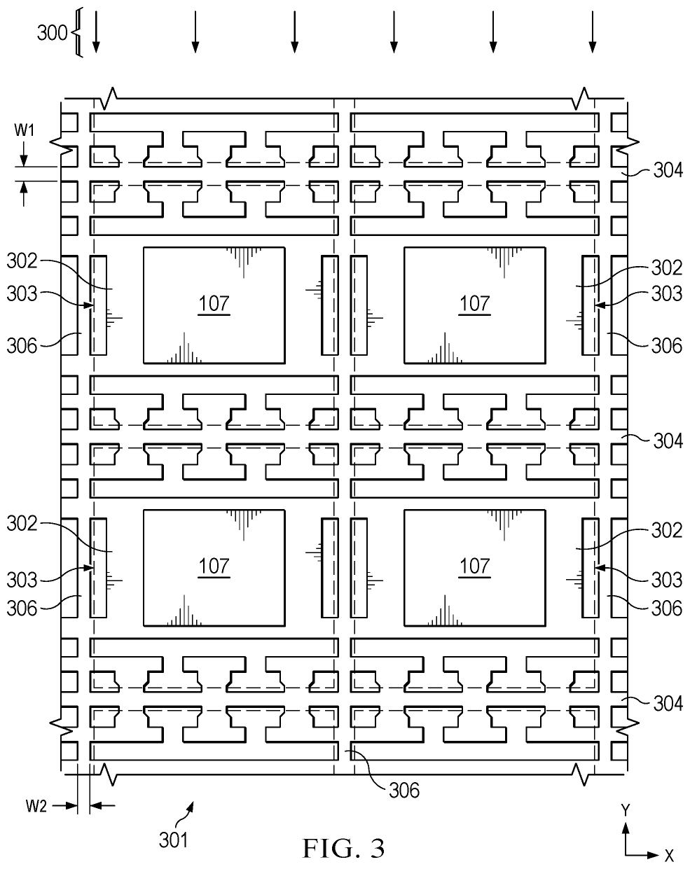

Referring now to FIGS. 2-9, another aspect provides a method of fabricating an electronic device. FIG. 2 shows a method 200 of fabricating an electronic device and FIGS. 3-9 show the electronic device 100 undergoing concurrent fabrication processing of multiple electronic devices in a panel array with rows and columns of unit areas according to an example implementation of the method 200. The method 200 begins at 202 in FIG. 2 with die attach processing. FIG. 3 shows implementation of a die attach process 300 performed on an example portion of a starting lead frame panel array or strip 301 (also referred to herein as a lead frame) with rows and columns of unit areas 303, each corresponding to a subsequently finished instance of an electronic device 100. As shown in FIG. 3, the starting lead frame 301 has a die attach pad structure 302 in each unit area 303. The lead frame 301 has laterally oriented first tie bars 304 with a first width W1 that extend between adjacent rows of unit areas 303 (e.g., left to right in the orientation of FIG. 3), as well as vertically oriented second tie bars 306 with a second width W2 that extend between adjacent columns of the unit areas 303 (e.g., up and down in the illustrated orientation). In the illustrated example, moreover, the first tie bars 304 are wider than the second tie bars 306 (e.g., W1 is greater than W2), although not a requirement of all possible implementations.

The die attach process 300 in FIG. 3 includes attaching instances of the semiconductor die 107 to corresponding instances of the die attach pad 302 in each of the unit areas 303. The die attach process 300 in one example includes dispensing or otherwise providing a die attach film (DAF) or other adhesive onto select portions of the respective die attach pads 302, followed by placement of the respective semiconductor dies 107 onto the adhesive film (not shown) over the die attach pad 302 of the corresponding unit area 303, for example, using automated pick and place equipment (not shown). The die attach process 300 can include an adhesive curing step, such as heating or other thermal processing, ultraviolet light exposure, etc., in order to cure the die attach film or adhesive in order to attach the semiconductor dies 107 onto the corresponding die attach pads 302.

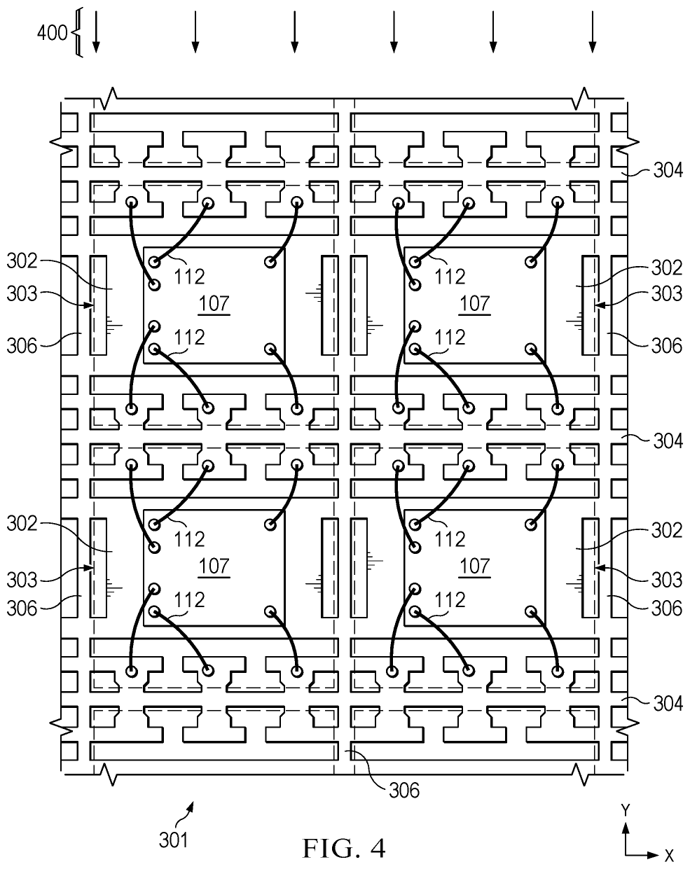

The method 200 continues at 204 and FIG. 2 with wire bonding to create the first and second bond wires 112 and 114. FIG. 4 shows one example, in which a wire bonding process 400 is performed to form the first bond wires 112, and FIG. 5 shows a wire bonding process 500 that forms the second bond wires 114. The wire bonding process 500 in FIG. 5 can be a continuation or part of the wire bonding process 400 or the bond wires 112 and 114 can be formed by separate wire bonding processes. In one example, the first bond wires 112 are formed as shown in FIG. 4 to provide a desired signal connections between the semiconductor die 107 and certain of the conductive leads 108 and 110 in each respective unit area 303 according to a desired circuit interconnection design for the electronic devices 100.

In this implementation, the second bond wires 114 are formed as shown in FIG. 5 to provide temporary electrical connection to prospective the intermediate lead locations for subsequent electroplating after the rows of unit areas 303 have been separated from one another. As shown in FIG. 5, for example, the second bond wires 114 in the illustrated portion of the lead frame panel array 301 cross over the vertically oriented second tie bars 306 to form electrical connections between each of the prospective intermediate lead locations in each unit area 303 and a conductive feature (e.g., a lead, a die attach pad, a tie bar, etc.) of a neighboring unit area 303 in the same row. In one implementation, a single wire bonding tool (not shown) is used to sequentially form the first bond wires 112 (e.g., FIG. 4) for the entire panel array, followed by sequential formation of the second bond wires 114 (e.g., FIG. 5) for the entire panel array. In another implementation, the wire bonding tool forms the first and second bond wires 112 and 114 in a given row of the unit areas 303 before starting the next row. Any suitable sequence of bond wire formation can be used in further implementations.

The illustrated example shows four full unit areas 303 along with portions of adjacent unit areas, with an instance of the second bond wire 114 that has one end connected to the prospective intermediate conductive lead in the bottom row of the unit area 303 and the lower left quadrant unit area 303 and crosses over (e.g., overlies) one of the first bond wires 112 that is connected between a bond pad of the corresponding semiconductor die 107 and the lower right perspective end conductive lead. This example instance of the second bond wire 114 has another end connected to a die attach pad 302 of the unit area 303 in the lower right illustrated quadrant.

Any suitable bond wire interconnection sequence and/or configuration can be used that provides the desired signal connections via first bond wires 112 and temporary electrical interconnections for electroplating via second bond wires 114, where the second bond wires 114 remain intact to provide the desired electrical connection after the first tie bars 304 are cut to separate adjacent rows of the unit areas 303 and are subsequently cut when the second tie bars 306 are cut to separate finished electronic devices 100 from the rows and columns of the panel array configuration.

The wire bonding process at 204 in FIG. 2 in one example includes forming one or more instances of the first bond wire 112 to connect a corresponding first conductive lead 108, 110 of a first unit aera 303 to the semiconductor die 107 of the first unit area 303, and forming one or more instances of the second bond wire 114 to connect a second conductive lead 108, 110 of the first unit aera 303 to a conductive feature of a second unit area 303 of the lead frame panel array 301, whether the second unit area 303 is a direct neighbor of the first unit area 303, or another unit area 303 in the same row as the first unit area 303, such that a temporary electrical connection is provided to facilitate subsequent electroplating of a cut side of each of the prospective conductive leads 108, 110. In another example, further instances of the second bond wire 114 can be formed at 204 to provide temporary electrical connection to one or more of the end conductive leads and/or multiple instances of the second bond wire 114 can be formed to provide multiple bond wire electrical connections to a given prospective end for intermediate conductive lead to improve the subsequent electroplating process and the quality of the plated surface thereof.

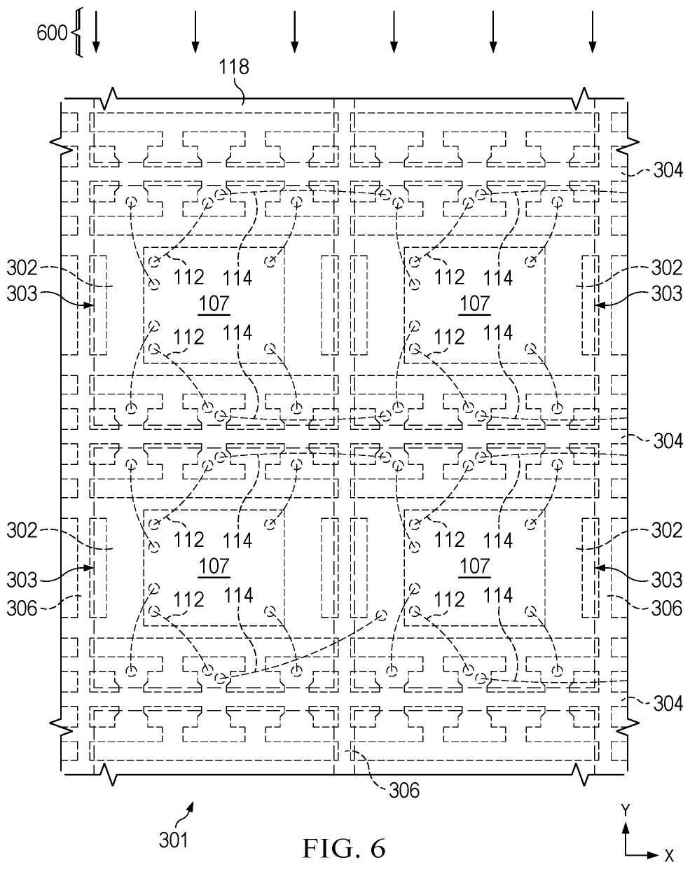

The method 200 continues with molding processing at 206 in FIG. 2 before the laterally extending first tie bars 304 are cut. FIG. 6 shows one example, in which a molding process 600 is performed that forms the molded package structure 118. The illustrated example provides a single mold cavity for multiple unit areas 303 of the array structure, such as one molded structure formed by a single mold cavity (not shown). In another example, multiple mold cavities can be used for the array structure, such as column-wise mold cavities (not shown), etc. The molding process 600 forms the molded package structure 118 in each unit area 303 that encloses the semiconductor die 107 and the instances of the first bond wire 112 of the unit areas 303 and also encloses the instances of the second bond wire 114 in the unit areas 303.

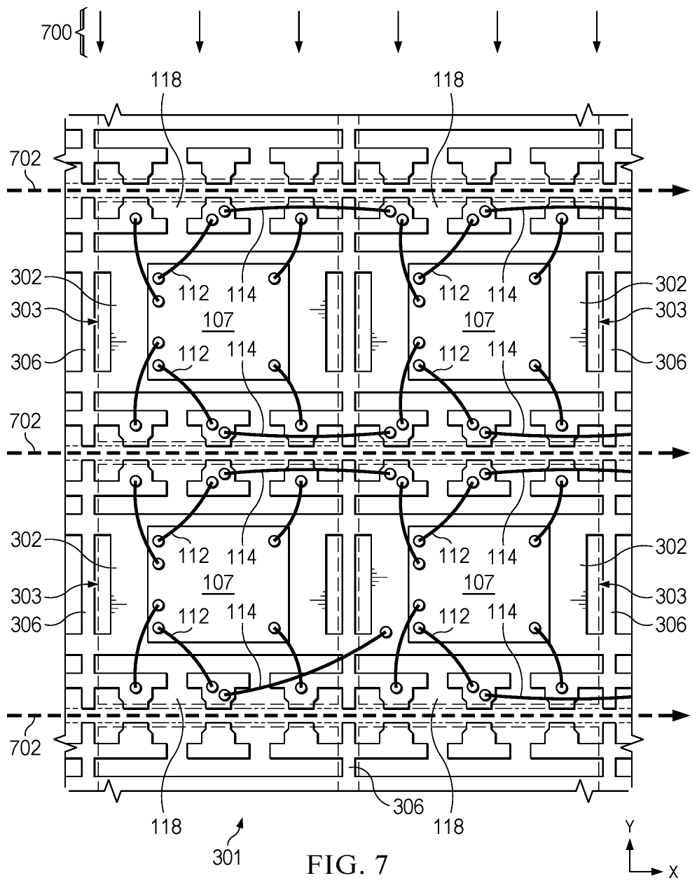

At 208 in FIG. 2, the method 200 continues with cutting along the row direction (e.g., a first direction). FIG. 7 shows one example, in which a first cutting process 700 is performed using one or more cutting saws, lasers, or other cutting tools (not shown) that cuts through the laterally extending first tie bars 304 along the lines 702. The cutting process 700 includes cutting the conductive tie bar features 304 of the lead frame panel array 301 along a first direction (e.g., left to right in FIG. 7) between given unit areas 303 and a corresponding neighboring unit area 303 of the lead frame panel array 301 to separate the conductive leads 108, 110 of given unit areas 303 from a conductive structure of the neighboring unit area 303 of the lead frame panel array 301.

In one implementation, the first cutting process 700 uses a first, wide saw (not shown) that separates adjacent rows of the unit areas 303 and removes the original laterally extending tie bars 304. In this example, the first cutting process 700 is performed from the back of the lead frame panel array 301 such that the cutting saw or saws do not completely cut through the molding compound of the molded package structure 318, but instead cut through the lead frame metal (e.g., the tie bars 304 of FIGS. 3-6 above) to separate the conductive leads 108, 110 of adjacent array rows from one another as shown in FIG. 7. This cutting process 700 creates exposed cut sidewalls of the conductive leads 108 and 110 along the first and second rows of each respective unit area 303 to allow subsequent electroplating operations to form the respective plated surfaces 109 and 111 described above in connection with FIG. 1. In one example, the cutting process 700 is performed such that the lateral (e.g., left and right) ends of each row remain connected to a single unitary frame that encircles the rows and columns of the lead frame panel array 301, for example, to facilitate single point grounding or other reference connection to the conductive features of the unit areas 303 and subsequent plating operations.

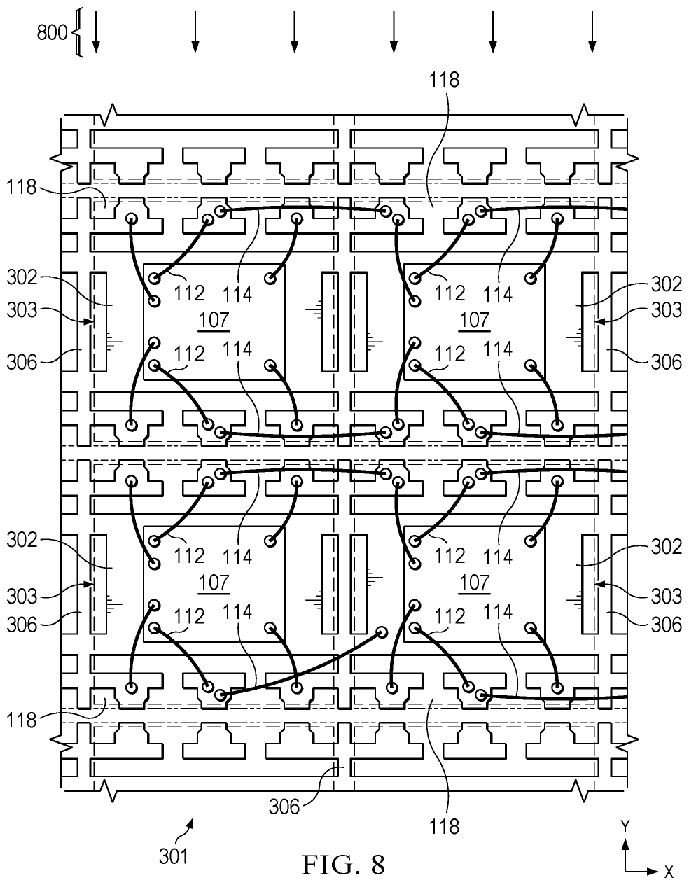

The method 200 continues at 210 in FIG. 2 with electroplating. FIG. 8 shows one example, in which an electroplating process 800 is performed that forms the plated surfaces 109 and 111 on sidewalls of the respective conductive leads 108 and 110 of each unit aera 303 of the panel array structure. In one implementation, a ground or other electrical reference of an electroplating tool (not shown) is connected to an outer frame (not shown) of the lead frame panel array 301, and the plating tool provides a controlled electric field in a chamber having suitable gaseous content (e.g., tin precursor) to electroplated the exposed metal features of the lead frame panel array with the desired plated coding to create the plated surfaces 109 and 111 of the respective conductive leads 108 and 110.

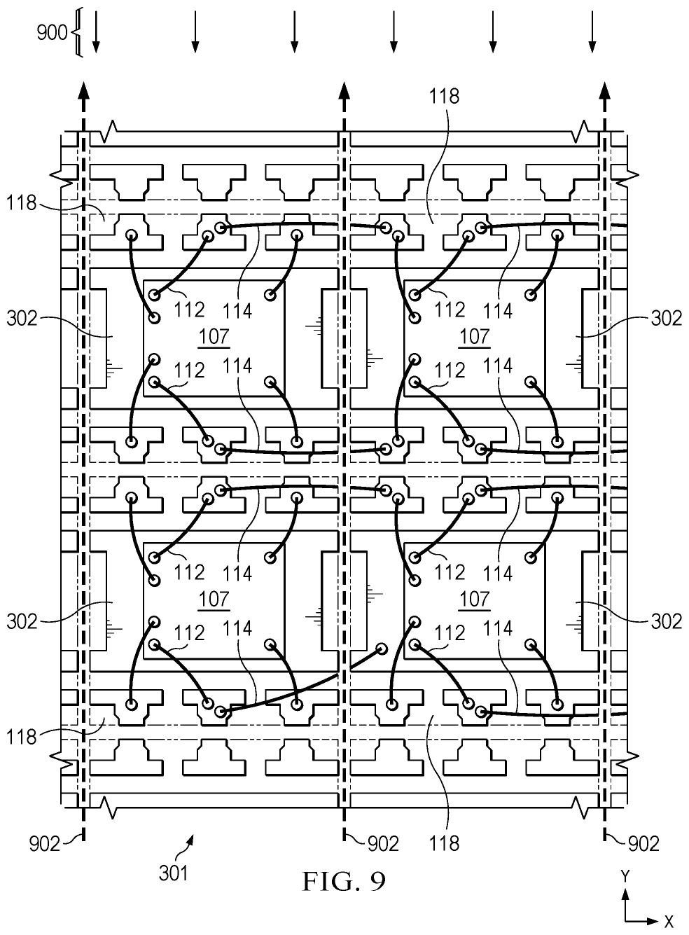

At 212 in FIG. 2, the method 200 continues with package separation processing. In the above described implementation, the package separation at 212 includes a second lateral cutting operation (not shown), for example, using a narrower or thinner cutting saw blade (not shown) to cut through the remaining portions of the molded package structure 118 between adjacent rows of unit areas 303. In one example, the second lateral cutting operation does not separate the individual rows of unit areas 303 from the frame that laterally surrounds the array structure, to facilitate further handling and processing of the lead frame panel array configuration. In this or another example, the package separation at 212 further includes vertical separation, such as using one or more cutting saw blades, lasers, or other separation equipment (not shown). FIG. 9 shows one example, in which a vertical cutting process 900 is performed that cuts along lines 902 through the vertically extending second tie bars 306 and portions of the molded package structure 118 to separate the individual finished packaged electronic devices 100 from the array structure. In one implementation, panel-wise final device probe testing (not shown) can be performed prior to the final cutting process 900. The vertical cutting process 900, moreover, cuts the second bond wires 114 of each of the electronic devices 100, leaving the unterminated ends 113 and 115 along the respective sides 104 and 103 of the finished electronic devices as described above in connection with FIGS. 1, 1A, and 1C.

Modifications are possible in the described examples, and other implementations are possible, within the scope of the claims.

What is claimed is:

1. An electronic device, comprising:
a semiconductor die;
conductive leads in first and second rows along respective opposite sides of a package structure;
a first bond wire having a first end connected to a first one of the conductive leads and a second end connected to the semiconductor die; and
a second bond wire having a first end connected to a second one of the conductive leads and an unterminated second end exposed along a further side of the package structure.

2. The electronic device of claim 1, having a small outline no-lead (SON) package, wherein:
the package structure has: opposite first and second sides; opposite third and fourth sides; and opposite fifth and sixth sides, the third and fourth sides being spaced apart from one another along a first direction, the fifth and sixth sides being spaced apart from one another along a second direction that is orthogonal to the first direction, and the first and second sides being spaced apart from one another along a third direction that is orthogonal to the first and second directions;
the first row of the conductive leads extends along the fifth side;
the second row of the conductive leads extends along the sixth side; and
the unterminated second end of the second bond wire is exposed along one of the third and fourth sides of the package structure.

3. The electronic device of claim 2, wherein:
the first row of the conductive leads includes first conductive end leads at opposite respective ends of the first row, and a first conductive intermediate lead between the first conductive end leads;
the second row of the conductive leads includes second conductive end leads at opposite respective ends of the second row, and a second conductive intermediate lead between the second conductive end leads; and
the first end of the second bond wire is connected to one of the first and second conductive intermediate leads.

4. The electronic device of claim 3, comprising a further bond wire having a first end connected to one of the first and second conductive end leads and an unterminated second end exposed along the further side of the package structure.

5. The electronic device of claim 3, comprising a further bond wire having a first end connected to one of a die attach pad and a tie bar, and an unterminated second end exposed along the further side of the package structure.

6. The electronic device of claim 1, wherein:
the first row of the conductive leads includes first conductive end leads at opposite respective ends of the first row, and a first conductive intermediate lead between the first conductive end leads;
the second row of the conductive leads includes second conductive end leads at opposite respective ends of the second row, and a second conductive intermediate lead between the second conductive end leads; and
the first end of the second bond wire is connected to one of the first and second conductive intermediate leads.

7. The electronic device of claim 6, comprising a further bond wire having a first end connected to one of the first and second conductive end leads and an unterminated second end exposed along the further side of the package structure.

8. The electronic device of claim 6, comprising a further bond wire having a first end connected to one of a die attach pad and a tie bar, and an unterminated second end exposed along the further side of the package structure.

9. The electronic device of claim 1, comprising a further bond wire having a first end connected to one of the conductive end leads and an unterminated second end exposed along the further side of the package structure.

10. The electronic device of claim 1, comprising a further bond wire having a first end connected to one of a die attach pad and a tie bar, and an unterminated second end exposed along the further side of the package structure.

11. The electronic device of claim 1, wherein one of the first and second bond wires overlies the other one of the first and second bond wires.

12. The electronic device of claim 1, wherein:
the first and second rows of the conductive leads include conductive end leads at opposite ends of the respective row and a conductive intermediate lead between the conductive end leads of the respective row; and
each of the conductive leads of the first and second rows has a plated surface exposed along the respective side of the package structure.

13. An electronic device, comprising:
a small outline no-lead (SON) package having a molded package structure and conductive leads with plated sidewalls exposed along opposite lateral sides of the package structure;
a semiconductor die at least partially enclosed by the molded package structure;
a first bond wire enclosed by the molded package structure and connected between a first one of the conductive leads and the semiconductor die; and
a second bond wire having a first end and an unterminated second end exposed along a further side of the package structure.

14. The electronic device of claim 13, wherein:
the conductive leads include conductive end leads at opposite respective ends of the respective lateral sides and a conductive intermediate lead between the conductive end leads; and
the first end of the second bond wire is connected to one of the first and second conductive intermediate leads.

15. The electronic device of claim 13, wherein:
the conductive leads include conductive end leads at opposite respective ends of the respective lateral sides and a conductive intermediate lead between the conductive end leads; and
the first end of the second bond wire is connected to one of the conductive end leads.

16. The electronic device of claim 13, wherein the first end of the second bond wire is connected to one of a die attach pad and a tie bar.

17. A method of fabricating an electronic device, the method comprising:
for a first unit area of a lead frame panel array having unit areas arranged in rows along a first direction and columns along an orthogonal second direction, forming a first bond wire to connect a first conductive lead of the first unit aera to a semiconductor die of the first unit area;
for the first unit area, forming a second bond wire to connect a second conductive lead of the first unit aera to a conductive feature of a second unit area of the lead frame panel array;
cutting a conductive feature of the lead frame panel array along a first direction between the first unit area and a neighboring third unit area of the lead frame panel array to separate the conductive leads of the first unit area from a conductive structure of the neighboring third unit area of the lead frame panel array;
performing an electroplating process that forms a plated surface on sidewalls of the conductive leads of the first unit aera; and
separating a packaged electronic device from the lead frame panel array.

18. The method of claim 17, further comprising, before cutting the conductive feature of the lead frame panel array, performing a molding process to form a molded package structure that encloses the semiconductor die and the first bond wire of the first unit area and encloses the second bond wire.

19. The method of claim 18, wherein separating the packaged electronic device from the lead frame panel array cuts the second bond wire.

20. The method of claim 17, wherein separating the packaged electronic device from the lead frame panel array cuts the second bond wire.
